(19) United States
(12) Patent Application Publication
(10) Pub. No.: US 2007/0035022 A1
(43) Pub. Date: Feb. 15, 2007

(54) Semiconductor device and method of manufacturing the same

(75) Inventor: Takeshi Yuzawa, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/500,963

(22) Filed: Aug. 8, 2006

(30) Foreign Application Priority Data
Aug. 9, 2005 (JP) 2005-230906

(51) Int. Cl. H01L 23/48; H01L 21/44

(52) U.S. Cl. 257/737; 438/613; 257/E23.02; 257/E23.021

(57) ABSTRACT

A semiconductor device, including: a semiconductor layer; an electrode pad formed above the semiconductor layer; an insulating layer formed over the electrode pad and having an opening which exposes at least part of the electrode pad; and a bump formed at least in the opening. The bump includes: a first bump layer formed in the opening; an underlayer formed above the first bump layer and the insulating layer positioned around the first bump layer; and a second bump layer formed on the underlayer.

Japanese Patent Application No. 2005-230906, filed on Aug. 9, 2005, is hereby incorporated by reference in its entirety.

### BACKGROUND OF THE INVENTION

The present invention relates to a semiconductor device and a method of manufacturing the same.

As the increase in the degree of integration of semiconductor integrated circuits and the reduction in size of semiconductor chips progress, mounting technology capable of dealing with reduced pitch terminal connection is demanded. As examples of mounting technology capable of easily dealing with such a demand, tape automated bonding (TAB) mounting used for a tape carrier package (TCP) and flip-chip mounting used for a chip size package (CSP) can be given. In these mounting technologies, a bump is generally formed on a pad of the semiconductor chip. A gold bump is typically used as the bump. A gold bump is generally formed by electroplating. A gold bump formation method by electroplating is given below.

FIG. 7 is a cross-sectional view showing a gold bump of a related-art semiconductor chip. A pad 502 as part of wiring connected with an internal integrated circuit is covered with an insulating layer (passivation film) 504 excluding the surface of the electrical connection region.

An under-bump metal layer (stacked layer of a barrier metal layer and an feeding metal layer) 506 is formed by sputtering. A bump formation resist layer 508 is formed by photolithography so that the electrical connection region of the pad 502 and its peripheral region are exposed. Gold is then deposited by electroplating corresponding to the pattern of the resist layer 508. After removing the resist layer 508, the under-bump metal layer 506 is wet-etched corresponding to the type of under-bump metal layer by using the deposited gold as a mask. Then, annealing and the like are performed to form a bump 510.

When forming the bump by the above formation method, the barrier metal layer is formed to have a deep depression (opening), as shown in FIG. 7. In electroplating, since the metal layer is deposited following the shape of the barrier metal layer, a depression 512 is formed in the surface of the bump 510 corresponding to the shape of the opening. The mounting capability may be affected when the surface of the bump is not flat. Therefore, formation of a bump with a flat surface has been demanded.

### SUMMARY

According to a first aspect of the invention, there is provided a semiconductor device, comprising:
a semiconductor layer;
an electrode pad formed above the semiconductor layer;
an insulating layer formed over the electrode pad and having an opening which exposes at least part of the electrode pad; and
a bump formed at least in the opening,
wherein the bump includes:
a first bump layer formed in the opening;
an underlayer formed above the first bump layer and the insulating layer positioned around the first bump layer; and
a second bump layer formed on the underlayer.

According to a second aspect of the invention, there is provided a method of manufacturing a semiconductor device, comprising:
forming an electrode pad above a semiconductor layer;
forming an insulating layer over the electrode pad, the insulating layer having a first opening which exposes at least part of the electrode pad;
forming a first bump layer in the first opening by electroless plating;
forming an underlayer on the first bump layer and the insulating layer around the first bump layer;
forming a mask layer on the underlayer, the mask layer having a second opening positioned at least above the first bump layer;
forming a second bump layer in the second opening by electroplating;
removing the mask layer; and
removing part of the underlayer by using the second bump layer as a mask.

### BRIEF DESCRIPTION OF THE SEVERAL VIEWS OF THE DRAWING

FIG. 1 is a cross-sectional view schematically showing a semiconductor device according to one embodiment of the invention.

FIG. 2 is a cross-sectional view showing a manufacturing step of a semiconductor device according to one embodiment of the invention.

FIG. 3 is a cross-sectional view showing a manufacturing step of a semiconductor device according to one embodiment of the invention.

FIG. 4 is a cross-sectional view showing a manufacturing step of a semiconductor device according to one embodiment of the invention.

FIG. 5 is a cross-sectional view showing a manufacturing step of a semiconductor device according to one embodiment of the invention.

FIG. 6 is a cross-sectional view showing a manufacturing step of a semiconductor device according to a modification of one embodiment of the invention.

FIG. 7 is a cross-sectional view showing a manufacturing step of a semiconductor device according to a related-art example.

### DETAILED DESCRIPTION OF THE EMBODIMENT

The invention may provide a method of manufacturing a semiconductor device capable of forming a bump with a flat surface, and a semiconductor device having a bump formed by this manufacturing method.

(1) According to one embodiment of the invention, there is provided a semiconductor device, comprising:
a semiconductor layer;
an electrode pad formed above the semiconductor layer;
an insulating layer formed over the electrode pad and having an opening which exposes at least part of the electrode pad; and
a bump formed at least in the opening,
wherein the bump includes:
a first bump layer formed in the opening;
an underlayer formed above the first bump layer and the insulating layer positioned around the first bump layer; and
a second bump layer formed on the underlayer.

This embodiment allows provision of a semiconductor device having a bump with a flat top surface. For example, when connecting a wiring pattern formed on a substrate and the top surface of a bump in a state in which the wiring pattern faces the bump, conductive particles are provided between the wiring pattern and the bump. According to this embodiment, the electrical connection properties of the particles can be improved. As a result, a semiconductor device exhibiting excellent electrical connection and improved reliability can be provided.

In this invention, when a specific layer B is formed on (or above) a specific layer A, the layer B may be directly formed on the layer A, or another layer may be interposed between the layer B and the layer A.

This embodiment may have the following features.

(2) In this semiconductor device,
a top surface of the first bump layer may be lower than a top surface of the insulating layer on the electrode pad.

(3) In this semiconductor device,
a top surface of the first bump layer may have almost the same height as a top surface of the insulating layer on the electrode pad.

(4) In this semiconductor device,
an integrated circuit may be formed in the semiconductor layer; and
at least one of the electrode pad and the second bump layer may be formed above the integrated circuit.

(5) According to one embodiment of the invention, there is provided a method of manufacturing a semiconductor device, comprising:
forming an electrode pad above a semiconductor layer;
forming an insulating layer over the electrode pad, the insulating layer having a first opening which exposes at least part of the electrode pad;
forming a first bump layer in the first opening by electroless plating;
forming an underlayer on the first bump layer and the insulating layer around the first bump layer;
forming a mask layer on the underlayer, the mask layer having a second opening positioned at least above the first bump layer;
forming a second bump layer in the second opening by electroplating;
removing the mask layer; and
removing part of the underlayer by using the second bump layer as a mask.

The method of manufacturing a semiconductor device according to this embodiment allows manufacture of a semiconductor device having a bump with a flat top surface. In this method of manufacturing a semiconductor device, the first bump layer is formed in the opening which exposes at least part of the electrode pad. Therefore, the underlayer can be formed on a surface with reduced unevenness (i.e. surface with improved flatness) in the subsequent step. This allows formation of the underlayer with a flat surface, whereby a problem can be prevented in which a depression is formed on the top surface of the second bump layer when forming the second bump layer by electroplating, as described with reference to the related-art example. As a result, a semiconductor device having a bump with a flat top surface can be manufactured.

Embodiments of the invention are described below with reference to the drawings.

1. Semiconductor device

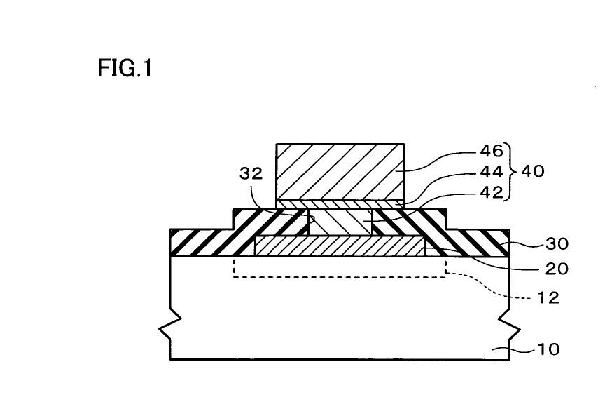

A semiconductor device according to one embodiment of the invention is described below with reference to FIG. 1. FIG. 1 is a cross-sectional view schematically showing the semiconductor device according to this embodiment.

As shown in FIG. 1, the semiconductor device according to this embodiment includes a semiconductor layer 10. An integrated circuit 12 may be formed in the semiconductor layer 10. The configuration of the integrated circuit 12 is not particularly limited. For example, the integrated circuit 12 may include an active element such as a transistor and a passive element such as a resistor, coil, or capacitor. The semiconductor layer 10 may be in the shape of a chip or a semiconductor wafer.

An electrode pad 20 having a specific pattern is formed on the semiconductor layer 10. The electrode pad 20 may be formed of a metal such as aluminum or copper. The electrode pad 20 may be formed over the integrated circuit.

An insulating layer 30 is formed over the electrode pad 20. The insulating layer 30 may be formed of SiO₂, SiN, a polyimide resin, or the like. The insulating layer 30 has an opening 32 which exposes at least part of the electrode pad 20 instead of covering the entire surface of the electrode pad 20. In the semiconductor device according to this embodiment, the square opening 32 is formed in the center region of the electrode pad 20. Note that the shape of the opening 32 is not limited to square. For example, the opening 32 may have a circular planar shape or a quadrilateral planar shape other than square.

In the semiconductor device according to this embodiment, a bump 40 is formed above the electrode pad 20 at least in the opening 32. Specifically, the bump 40 is formed on the exposed surface of the electrode pad 20. The bump 40 includes a first bump layer 42 formed in the opening 32, an underlayer 44 formed at least on the first bump layer 42, and a second bump layer 46 formed on the underlayer 44. As shown in FIG. 1, the first bump layer 42 is formed only in the opening 32. The first bump layer 42 has almost the same height as the top surface of the insulating layer 30 which encloses the opening 32. Specifically, the top surface of the first bump layer 42 and the top surface of the insulating layer 30 form a flat surface in the region in which the second bump layer described later is formed. As examples of the first bump layer 42, a nickel-containing layer formed by electroless plating and the like can be given.

The underlayer 44 is formed on the first bump layer 42 and the insulating layer 30 which encloses the first bump layer 42. The underlayer 44 may be a stacked layer of feeding conductive metal layers which exhibit effects when forming the barrier metal layer and the second bump layer 46 by electroplating, or a single layer of a material which achieves these effects. As examples of the underlayer 44, a titanium tungsten layer, a gold (Au) layer, and the like can be given.

The second bump layer 46 is formed on the underlayer 44. The second bump layer 46 has a pattern larger than that of the first bump layer 42 when viewed from the top side. The top surface of the second bump layer 46 is almost flat. As the second bump layer 46, a gold layer formed by electroplating or the like may be used.

The semiconductor device according to this embodiment has a flat mounting surface (or the top surface of the second bump layer 46). Therefore, the electrical connection properties of conductive particles provided between the bump 40 and a lead wire electrically connected with the bump 40 can be improved during mounting, for example, whereby mounting capability can be improved. As a result, the semiconductor device according to this embodiment allows provision of a semiconductor device exhibiting improved mounting capability and high reliability.

2. Method of Manufacturing Semiconductor Device

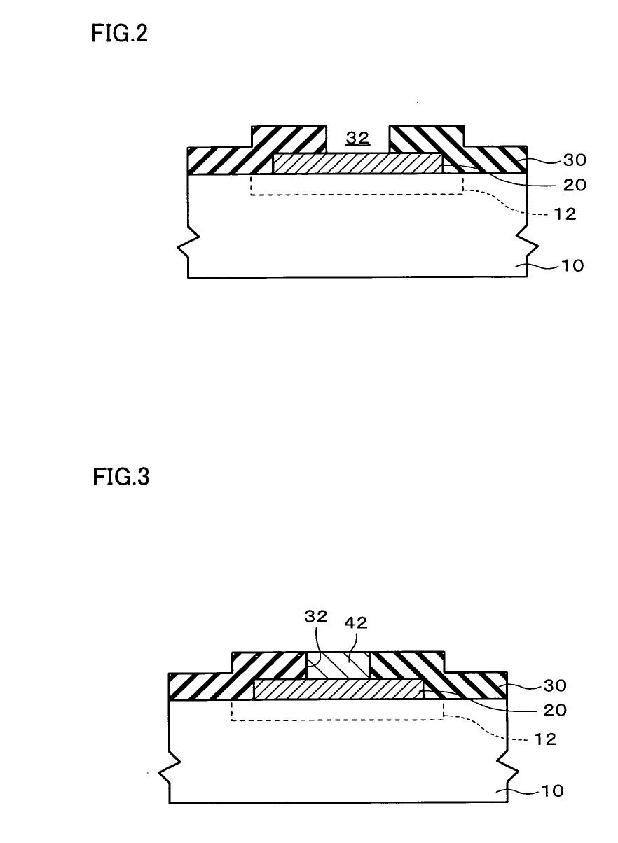

A method of manufacturing the semiconductor device shown in FIG. 1 is described below with reference to FIGS. 2 to 5. FIGS. 2 to 5 are views schematically showing the manufacturing steps of the semiconductor device according to this embodiment.

As shown in FIG. 2, the semiconductor layer 10 having a specific pattern is provided. The semiconductor layer 10 is the same as described above. An integrated circuit may be formed in the semiconductor layer 10. The semiconductor layer 10 may be in the shape of a chip or a semiconductor wafer. An insulating layer and a wiring layer (not shown) are stacked on the semiconductor layer 10, and the electrode pad 20 is formed on the stacked layers. The electrode pad 20 is electrically connected with the semiconductor layer 10 through an intermediate wiring layer. The insulating layer 30 is formed on the electrode pad 20. The insulating layer 30 may be formed by CVD, for example. The insulating layer 30 is patterned by known lithography and etching to expose the electrode pad 20. This allows the opening 32 to be formed in the insulating layer 30 to expose the center of the electrode pad 20. The insulating layer 30 may be formed of a single layer or a plurality of layers.

As shown in FIG. 3, the first bump layer 42 is formed in the opening 32. The first bump layer 42 is formed by electroless plating. An example of forming a nickel-containing metal layer as the first bump layer 42 on the electrode pad 20 formed of an aluminum layer is given below.

A zincate treatment is performed when forming the first bump layer 42. In the zincate treatment, Al on the surface of the electrode pad 20 is replaced with Zn. A metal (e.g. Ni) is then deposited. The semiconductor layer 10 is caused to come in contact with a treatment solution (e.g. electroless plating solution). Zn is replaced with Ni on the surface of the electrode pad 20 provided with the zincate treatment, whereby an Ni layer is deposited. The treatment temperature (temperature of the plating solution), the treatment time (plating time), the amount of treatment solution, the pH of the treatment solution, the number of treatment operations, and the like may be appropriately adjusted depending on the desired shape of the first bump layer 40. In more detail, the opening 32 is filled with the first bump layer 42 to form the first bump layer 42 with a flat surface. The underlayer formation surface described later can be provided with reduced unevenness by forming the first bump layer 42 in the opening 32 as described above.

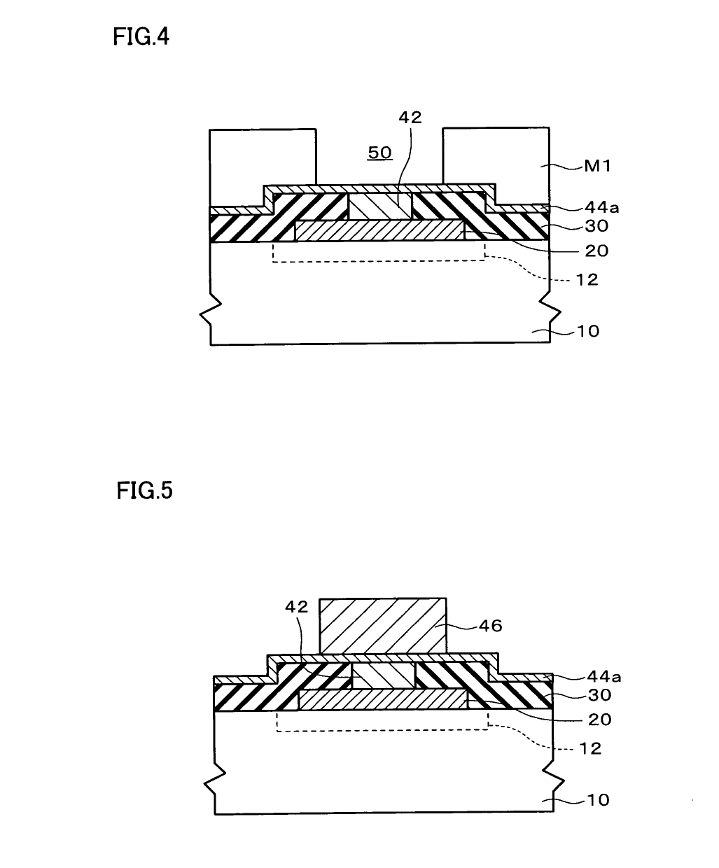

As shown in FIG. 4, an underlayer 44a is formed on the first bump layer 42 and the insulating layer 30. The underlayer 44a prevents diffusion between the electrode pad 20 and the second bump layer 46 described later. The underlayer 44a may be formed of one or more layers. The underlayer 44a may be formed by sputtering, for example. A titanium tungsten (TiW) layer or the like may be formed as the underlayer 44a. When forming the underlayer by stacking two or more layers, a gold (Au) layer may be formed on a titanium tungsten (TiW) layer. A mask layer M1 is formed on the underlayer 44a. A resist layer may be used as the mask layer M1. The mask layer M1 has an opening 50 in the region including the first bump layer 42.

As shown in FIG. 5, the second bump layer 46 is formed in the opening 50. The second bump layer 46 formed by electroplating. As the material for the second bump layer 46, gold (Au) may be used. After removing the mask layer M1, the exposed underlayer 44a is removed. Specifically, the underlayer 44a is removed by using the second bump layer 46 as a mask. The underlayer 44a is removed by a removal method appropriate for the material. This allows the underlayer 44 to be formed under the second bump layer 46, whereby the bump 40 including the first bump layer 42, the underlayer 44, and the second bump layer 46 can be formed.

The semiconductor device according to one embodiment of the invention may be manufactured by the above steps. The method of manufacturing a semiconductor device according to this embodiment allows manufacture of a semiconductor device which includes the bump 40 with a flat top surface. In this method of manufacturing a semiconductor device, the first bump layer 42 is formed in the opening 32 which exposes at least part of electrode pad 20. Therefore, the underlayer 44a can be formed on a surface with reduced unevenness. As a result, a problem in which the depression 512 is formed on the top surface of the bump 510 due to the opening, as described with reference to the related-art example, can be prevented when forming the second bump layer 46 on the underlayer 44a by electroplating.

3. Modification

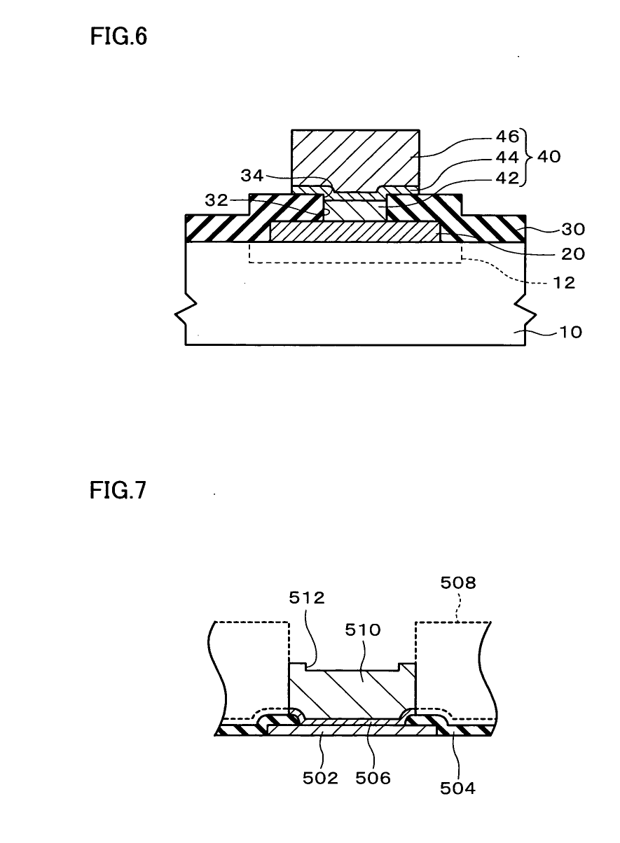

A modification of the semiconductor device according to one embodiment of the invention is described below with reference to FIG. 6. FIG. 6 is a cross-sectional view schematically showing the semiconductor device according to this modification. This modification differs from the semiconductor device according to the above embodiment as to the position of the top surface of the first bump layer 42. Note that description of the same configurations and members as in the above embodiment is omitted.

As shown in FIG. 6, the first bump layer 42 is formed on the electrode pad 20 and in the opening 32. The top surface of the first bump layer 42 is formed at a position lower than the position of the top end of the opening 32. Specifically, the semiconductor device according to this modification includes a depression 34 formed by the top surface of the first bump layer 42 and the side surface of the opening 32. Since the depression 34 is shallower than the opening 32, the underlayer 44 can be formed on a surface with reduced unevenness in comparison with the case where the first bump layer 42 is not formed. Therefore, the second bump layer 46 with improved flatness can be formed on the underlayer 44. As a result, the semiconductor device according to this modification allows provision of a semiconductor device exhibiting. the same advantage as the semiconductor device according to the above embodiment and provided with improved reliability.

The invention is not limited to the above-described embodiments, and various modifications can be made. For example, the invention includes various other configurations substantially the same as the configurations described in the embodiments (in function, method and result, or in objective and result, for example). The invention also includes a configuration in which an unsubstantial portion in the described embodiments is replaced. The invention also includes a configuration having the same effects as the configurations described in the embodiments, or a configuration able to achieve the same objective. Further, the invention includes a configuration in which a publicly known technique is added to the configurations in the embodiments.

Although only some embodiments of the invention have been described in detail above, those skilled in the art will readily appreciate that many modifications are possible in the embodiments without departing from the novel teachings and advantages of this invention. Accordingly, all such modifications are intended to be included within the scope of this invention.

What is claimed is:

1. A semiconductor device, comprising:
a semiconductor layer;
an electrode pad formed above the semiconductor layer;
an insulating layer formed over the electrode pad and having an opening which exposes at least part of the electrode pad; and
a bump formed at least in the opening,
wherein the bump includes:
a first bump layer formed in the opening;
an underlayer formed above the first bump layer and the insulating layer positioned around the first bump layer; and
a second bump layer formed on the underlayer.

2. The semiconductor device as defined in claim 1,
wherein a top surface of the first bump layer is lower than a top surface of the insulating layer on the electrode pad.

3. The semiconductor device as defined in claim 1,
wherein a top surface of the first bump layer has almost the same height as a top surface of the insulating layer on the electrode pad.

4. The semiconductor device as defined in claim 1,
wherein an integrated circuit is formed in the semiconductor layer; and
wherein at least one of the electrode pad and the second bump layer is formed above the integrated circuit.

5. A method of manufacturing a semiconductor device, comprising:
forming an electrode pad above a semiconductor layer;
forming an insulating layer over the electrode pad, the insulating layer having a first opening which exposes at least part of the electrode pad;
forming a first bump layer in the first opening by electroless plating;
forming an underlayer on the first bump layer and the insulating layer around the first bump layer;
forming a mask layer on the underlayer, the mask layer having a second opening positioned at least above the first bump layer;
forming a second bump layer in the second opening by electroplating;
removing the mask layer; and
removing part of the underlayer by using the second bump layer as a mask.
